(19) United States
(12) Patent Application Publication
(10) Pub. No.: US 2025/0309002 A1
(43) Pub. Date: Oct. 2, 2025

(54) METHOD FOR INSPECTING SEMICONDUCTOR BONDED STRUCTURE

(71) Applicant: TAIWAN SEMICONDUCTOR MANUFACTURING COMPANY LTD., HSINCHU (TW)

(72) Inventors: CHAN-SHUO HSU, HSINCHU CITY (TW); CHENG WEI TSAI, HSINCHU CITY (TW); SHIN-HUANG CHEN, NANTOU COUNTY (TW)

(21) Appl. No.: 18/620,991

(22) Filed: Mar. 28, 2024

(51) Int. Cl. H01L 21/66; H01L 23/00; H01L 25/16

(52) U.S. Cl. CPC H01L 22/12; H01L 22/14; H01L 24/81; H01L 25/167; H01L 2224/81125

(57) ABSTRACT

The present disclosure provides a method for inspecting a semiconductor bonded structure. The method includes: obtaining a first image of a first connector of a first semiconductor structure; obtaining a second image of a second connector of a second semiconductor structure, wherein the second connector corresponds to the first connector; deriving an overlay image based on the first image and the second image; and evaluating an alignment of the first connector and the second connector based on the overlay image.

### BACKGROUND

A three-dimensional integrated circuit (3DIC) includes a semiconductor bonded structure with two or more layers of active electronic components integrated together, usually by being vertically stacked and connected. Various forms of 3DIC technology are currently being developed, including die-on-die stacking, die-on-wafer stacking and wafer-on-wafer stacking. In 3DIC technology, electronic components are built on two or more substrates and packaged to form a single integrated circuit. The electronic components are aligned and bonded together. Vertical connections between the electronic components are formed, such as through-silicon vias (TSVs), conductive connectors and optical connectors.

The 3DIC technology offers promise of technical advantages, in that it allows greater functionality to be provided in a smaller footprint and with increased speed. However, implementation of the 3DIC technology faces certain challenges, such as a requirement of precise alignment of vertical connections. Therefore, there is a need to improve a semiconductor manufacturing process.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a flow diagram showing a method for inspecting a semiconductor bonded structure, in accordance with some embodiments of the present disclosure.

FIGS. 2 to 30 are schematic cross-sectional or top views illustrating sequential operations of the method in FIG. 1, in accordance with some embodiments of the present disclosure.

### DETAILED DESCRIPTION OF THE DISCLOSURE

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In some embodiments, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass orientations of the device in use or operation in some embodiments different from the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” and “about” generally mean within a value or range which can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

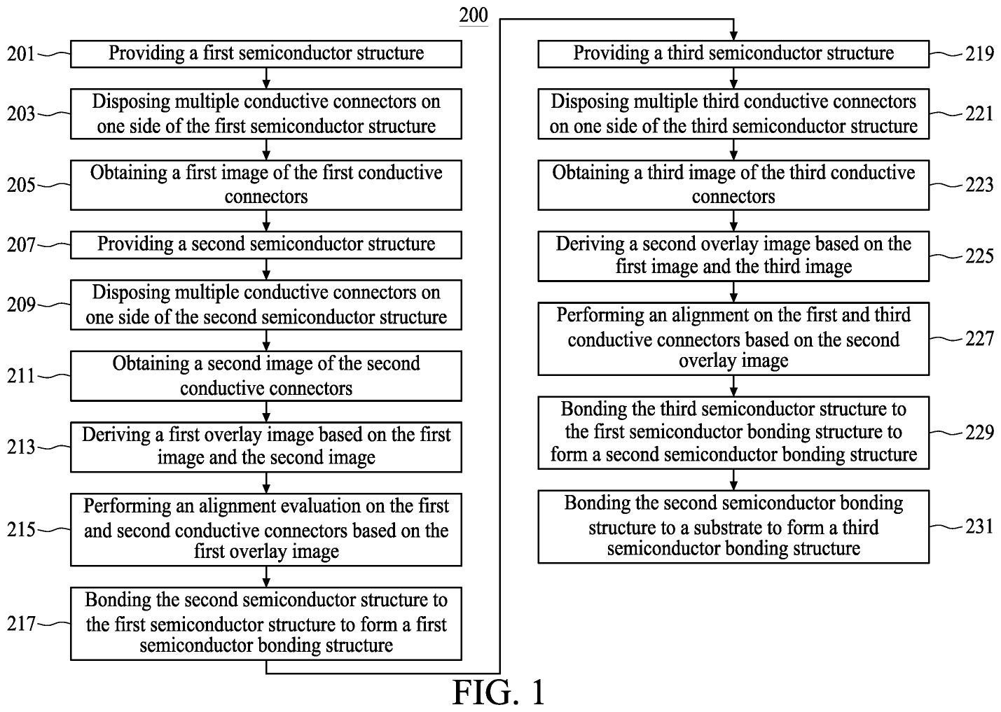

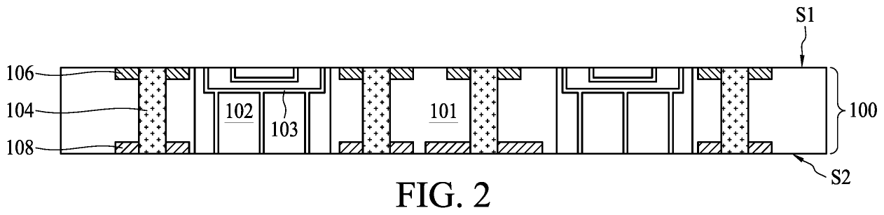

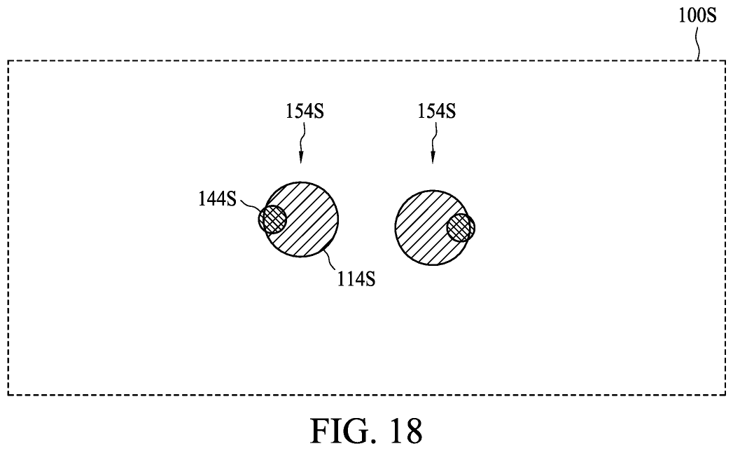

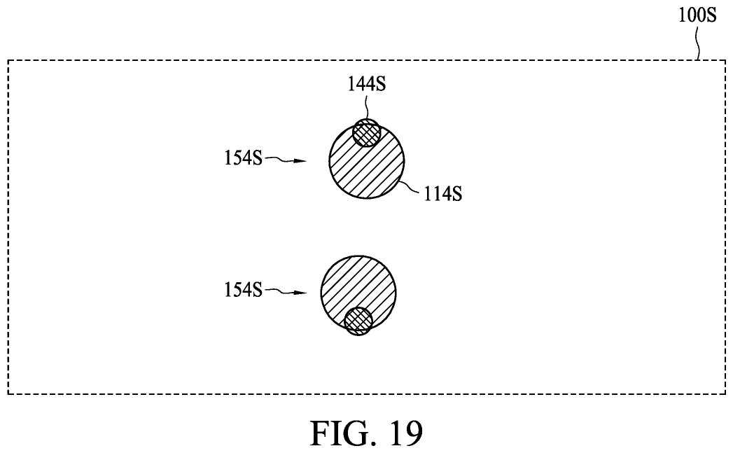

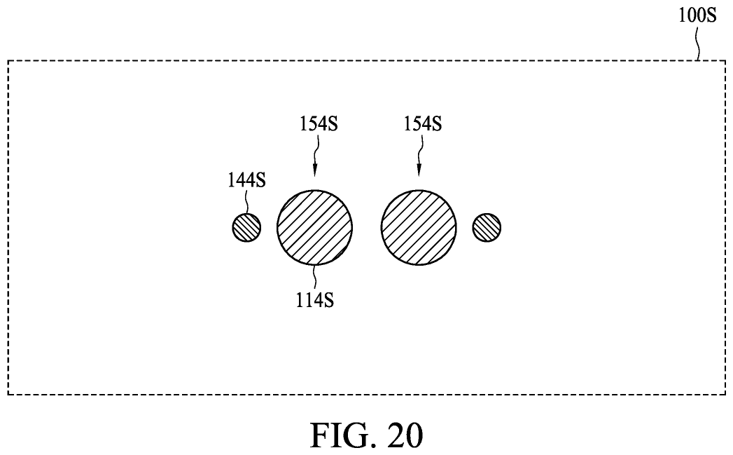

FIG. 1 is a flow diagram showing a method 200 for inspecting a semiconductor bonded structure. FIGS. 2 to 30 are schematic cross-sectional or top views illustrating sequential operations of the method 200 in FIG. 1.

In operation 201, a first semiconductor structure 100 is provided, as shown in FIG. 2. In some embodiments, the first semiconductor structure 100 is an interposer, which can be used to provide signal transmission, power distribution or thermal management. In some other embodiments, the first semiconductor structure 100 is a structure other than an interposer. The first semiconductor structure 100 may include a substrate 101, one or more electronic devices 102 disposed within the substrate 101, multiple through vias 104 extending through the substrate 101, multiple first metal layers 106 disposed on a first side S1 of the substrate 101 and multiple second metal layers 108 disposed on a second side S2 of the substrate 101.

The substrate 101 may be made of silicon (Si), a conductive material, an organic material, or a combination thereof. In some embodiments, the electronic device 102 is an interconnect device, such as a local silicon interconnect (LSI). The LSI may be used to provide connection between adjacent circuit elements within, above or below the first semiconductor structure 100. In some embodiments, the electronic device 102 includes one or more die bridges 103 or fine-pitch RDLs. The die bridge 103 may be a metallization layer formed within the electronic device 102 and used to provide electrical routing between two adjacent dies near the electronic device 102. As such, the electronic device 102 may be used to provide communication between two integrated circuit dies.

In some embodiments, the electronic device 102 is a device other than an interconnect device. The electronic device 102 may include active devices such as transistors, diodes, or the like. The electronic device 102 may include passive components such as capacitors, resistors, inductors, or the like. The electronic device 102 may further include electronic components or memory devices. In some embodiments, the electronic device 102 includes a central processing unit (CPU), a microcontroller, or the like. In some other embodiments, the electronic device 102 includes one or more layers of wiring and is substantially free of an active or passive device. The electronic devices 102 may have any suitable lateral dimensions. In some embodiments, when the electronic devices 102 are interconnect devices, other active or passive components are also disposed in the first semiconductor structure 100.

In some embodiments, the through vias 104, the first metal layers 106 and the second metal layers 108 are respectively formed of conductive materials such as copper, aluminum, gold, nickel, silver, palladium, tin, similar materials, or combinations thereof. Each of the first metal layers 106 is electrically connected to one of the through vias 104. Each of the second metal layers 108 is electrically connected to one of the through vias 104. The first metal layers 106 and the second metal layers 108 shown in FIG. 2 are merely illustrative. The first metal layers 106 and the second metal layers 108 may separately include multiple stacked interconnects within a common dielectric layer. In some embodiments, the first metal layers 106 or the second metal layers 108 are redistribution layers (RDL). In FIG. 2, both sides S1 and S2 of the substrate 101 include metal layers disposed therein; in some other embodiments, only a single side of the substrate 101 includes metal layers disposed therein.

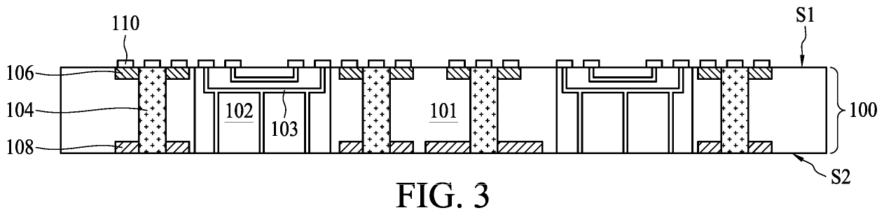

In operation 203, multiple conductive connectors 110 are disposed on the first side S1 of the first semiconductor structure 100, as shown in FIG. 3. The conductive connectors 110 may be formed of metals such as copper (Cu), aluminum (Al), gold (Au), nickel (Ni), silver (Ag), platinum (Pt), tin (Sn), or combinations thereof. The conductive connectors 110 can provide the electronic device 102 with electrical connections to other components subsequently formed on the electronic device 102. In some embodiments, some of the conductive connectors 110 are formed on and electrically connected to the through vias 104, some of the conductive connectors 110 are formed on and electrically connected to the first metal layers 106, and some of the conductive connectors 110 are formed on and electrically connected to the electronic devices 102. The conductive connectors 110 may have various configurations. For example, the conductive connectors 110 may be solder balls, bumps, pads or pillars. The metal pillars may be solder-free and/or may have substantially vertical sidewalls. In some embodiments, one or more types of the conductive connectors 110 are disposed on the first semiconductor structure 100. For example, the conductive connectors 110 respectively disposed on the through via 104, the first metal layer 106 and the electronic device 102 may be same as or different from each other.

Although not specifically depicted, additional metallization layers may be formed on the first side S1 or the second side S2 of the substrate 101 and electrically connected to the electronic devices 102, the through vias 104, the first metal layers 106 or the second metal layers 106, to provide additional circuitry. Furthermore, passivation layers or polymer layers may be formed on the metallization layers to provide protection.

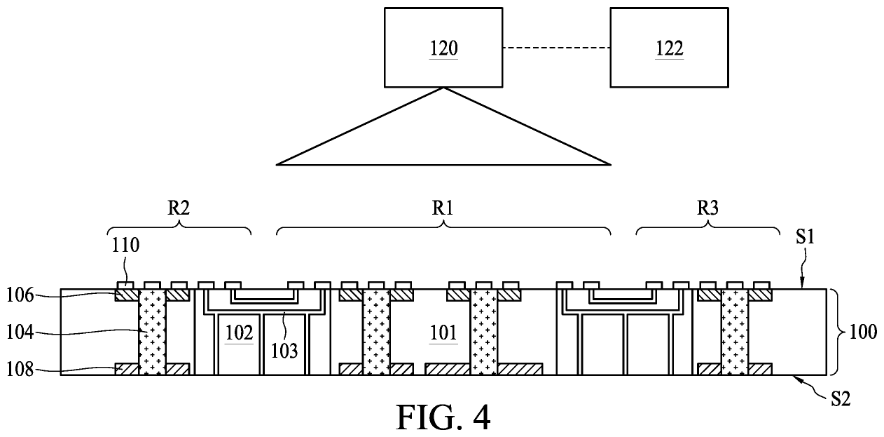

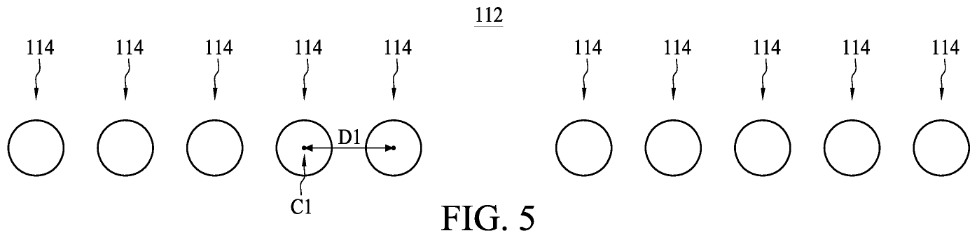

In operation 205, a first image 112 of the conductive connectors 110 is obtained, as shown in FIGS. 4 and 5. Referring to FIG. 4, in some embodiments, an imaging device 120 is used to take images of the conductive connectors 110. The imaging device 120 may be electrically coupled to a processor 122. Signals or data may be transmitted from the imaging device 120 to the processor 122. In some embodiments, the processor 122 includes an image-processing software that can identify features of an image or photo. The image-processing software may be used to analyze images taken by the imaging device 120. The imaging device 120 may be movable over the first semiconductor structure 100. For example, the imaging device 120 can focus on a region R1, R2 or R3 of the first semiconductor structure 100. In some embodiments, the imaging device 120 automatically focuses on a portion of the conductive connectors 110 in the region R1.

Referring to FIG. 5, the first image 112 is a top view of portions of the conductive connectors 110 in the region R1 of the first semiconductor structure 100. The first image 112 includes multiple connector images 114 of the corresponding conductive connectors 110. Images of other elements of the first semiconductor structure 100 are not shown in FIG. 5 for a purpose of simplicity. In some embodiments, the processor 122 is capable of deriving a distance D1 between center points C1 of two adjacent connector images 114. In some embodiments, the distance D1 is correlated to an actual distance between centers of the corresponding conductive connectors 110. Although not specifically illustrated, images of portions of the conductive connectors 110 in the regions R2 and R3 can be obtained in operation 205.

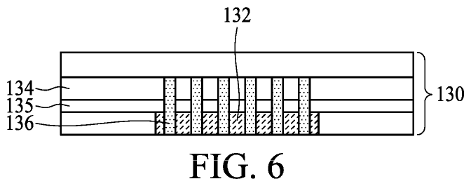

In operation 207, a second semiconductor structure 130 is provided, as shown in FIG. 6. The second semiconductor structure 130 may include multiple electronic devices 132 and 134, multiple through vias 136, and multiple metal layers (not shown). In some embodiments, the second semiconductor structure 130 is a system on chip (SOC) or a system on integrated circuit (SOIC) that integrates various electronic devices 132 and 134 in a single chip. The electronic devices 132 and 134 may include application specific integrated-circuit (ASIC) dies, CPU chips, graphics processing unit (GPU) chips, field-programmable gate array (FPGA) units, microcontrollers, power management integrated circuit (PMIC) dies, radio frequency (RF) dies, sensor dies, micro-electro-mechanical-system (MEMS) dies, signal processing dies (e.g., digital signal processing (DSP) dies), front-end dies (e.g., analog front-end (AFE) dies), the like, or a combination thereof. In some embodiments, the second semiconductor structure 130 includes passive components (e.g., capacitors, resistors, inductors, etc.). A glue layer 135 may be disposed between the electronic devices 132 and 134. The electronic devices 132 and 134 may be same as or different from each other. Relative positions and sizes of the electronic devices 132 and 134 shown in FIG. 6 are merely illustrative. In some embodiments, the electronic device 132 is disposed horizontally adjacent to the electronic device 134.

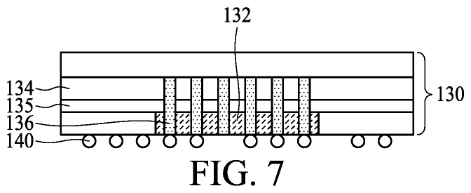

In operation 209, multiple conductive connectors 140 are disposed on one side of the second semiconductor structure 130, as shown in FIG. 7. The conductive connectors 140 may be formed of metals such as copper (Cu), aluminum (Al), gold (Au), nickel (Ni), silver (Ag), platinum (Pt), tin (Sn), or combinations thereof. The conductive connectors 140 can provide the electronic devices 132 and 134 with electrical connections to other components. The conductive connectors 140 are designed in correspondence to the conductive connectors 110 of the first semiconductor structure 100. The conductive connectors 140 may be electrically connected to the through vias 136 and the electronic devices 132 and 134. The conductive connectors 140 may have various configurations. For example, the conductive connectors 140 may be solder balls, bumps, pads or pillars. The metal pillars may be solder-free and/or may have substantially vertical sidewalls. In some embodiments, the conductive connectors 140 are micro bumps (ubumps) which have a diameter less than 50 micrometers.

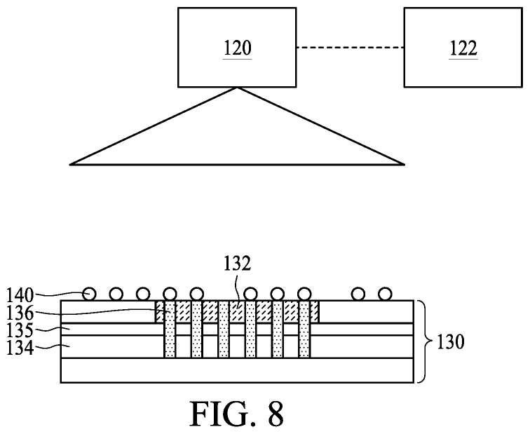

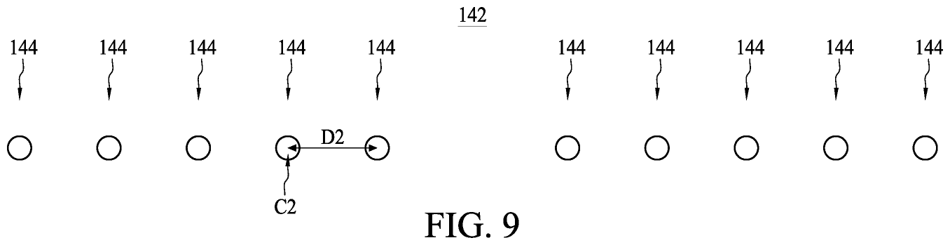

In operation 211, a second image 142 of the conductive connectors 140 is obtained, as shown in FIGS. 8 and 9. Referring to FIG. 8, the imaging device 120 can automatically focus on the conductive connectors 140.

Referring to FIG. 9, the second image 142 is a top view of the conductive connectors 140 on the second semiconductor structure 130. The second image 142 includes multiple connector images 144 of the corresponding conductive connectors 140. Images of other elements of the second semiconductor structure 130 are not shown in FIG. 9 for a purpose of simplicity. In some embodiments, the processor 122 is capable of deriving a distance D2 between center points C2 of two adjacent connector images 144. In some embodiments, the distance D2 correlates to an actual distance between centers of the corresponding conductive connectors 140.

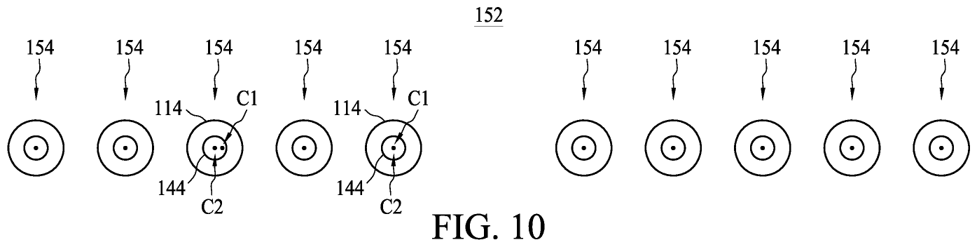

In operation 213, an overlay image 152 based on the first image 112 and the second image 142 is derived, as shown in FIGS. 10 to 14. Referring to FIG. 10, the processor 122 may be used to overlap the second image 142 of FIG. 9 with the first image 112 of FIG. 5 to generate the overlay image 152. In some embodiments, the overlay image 152 is used to monitor an alignment degree when the conductive connectors 140 are bonded to the conductive connectors 110. Therefore, the first image 112 and the second image 142 can be used as monitor patterns. The overlay image 152 includes multiple connector overlay images 154 formed from the connector images 114 and 144.

In some embodiments, the overlay image 152 is derived by aligning each connector image 114 with its corresponding connector image 144. In principle, the center points C2 of the connector images 144 should be aligned with the center points C1 of the connector images 114. However, in some cases, when most of the center points C1 and C2 are aligned, some of the center points C1 and C2 may not be aligned, i.e., the center points C1 and C2 have deviations or shifts. Such problem may come from a fact that the first semiconductor structure 100 with the conductive connectors 110 and the second semiconductor structure 130 with the conductive connectors 140 are produced by different manufacturers. Specifications related to size, pitch or shape of the conductive connectors 110 may not be consistent with those of the conductive connectors 140. Another possibility is that one or more of the conductive connectors 110 or 140 may be displaced during manufacturing. Therefore, when some of the connector images 144 shift from their corresponding connector images 114, for example, the center points C2 deviate from their corresponding center points C1, the first image 112 and the second image 142 are aligned in such a way that an overall deviation of shifts between the connector images 144 and the connector images 114 is minimized.

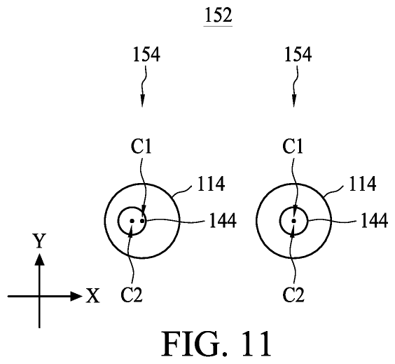

FIGS. 11 to 14 show four classifications based on different overlay images 152. Referring to FIG. 11, although not every center point C2 is aligned with its corresponding center point C1, every connector image 144 is within its corresponding connector image 114. Such overlay image 152 may be referred to as an “enclosure” or a “complete overlap.”

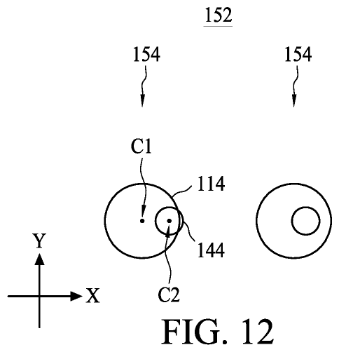

Referring to FIG. 12, the center points C2 deviate from their corresponding center points C1 mainly along an X direction. Such overlay image 152 may be referred to as an “X shift.”

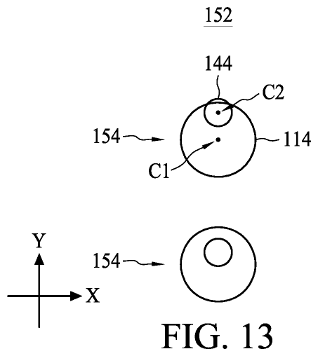

Referring to FIG. 13, the center points C2 deviate from their corresponding center points C1 mainly along a Y direction. Such overlay image 152 may be referred to as a “Y shift.” The X shift and Y shift may each be referred to as a “partial overlap.”

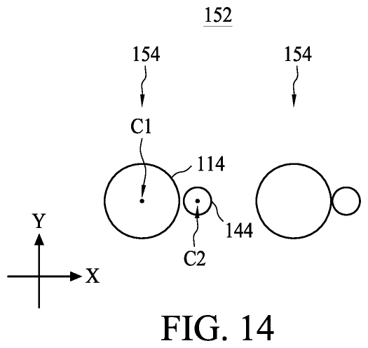

Referring to FIG. 14, once a connector image 144 falls outside its corresponding connector image 114, such overlay image 152 may be referred to as a “non-overlap.”

In operation 215, an alignment evaluation is performed on the conductive connectors 140 and the conductive connectors 110 based on the overlay image 152. In some embodiments, before the second semiconductor structure 130 is mounted on the first semiconductor structure 100, an alignment of the conductive connectors 140 with the corresponding conductive connectors 110 is evaluated to reduce possible bonding issues. In some embodiments, the alignment evaluation includes determining whether a portion of the first image 112 is out of the second image 142 or a portion of the second image 142 is out of the first image 112. The alignment evaluation may be a monitored item when manufacturing a semiconductor bonded structure. If the alignment evaluation shows a portion of the connector image 114 is out of the connector image 144 or a portion of the connector image 144 is out of the connector image 114 (i.e., a partial overlap or a non-overlap is present), an examination operation needs to be performed on the corresponding conductive connectors 110 and 140 causing such shift or non-overlap.

Still referring to FIGS. 12 to 14, the X-shift, Y-shift or non-overlap overlay image 152 indicates a potential electrical problem that may arise after the second semiconductor structure 130 is bonded to the first semiconductor structure 100. The examination operation is configured to determine whether respective positions or sizes of the conductive connectors 110 and 140 satisfy a predetermined standard. If one or more of the conductive connectors 110 and 140 do not satisfy the predetermined standard, an adjustment operation needs to be performed on the conductive connectors 110 and 140 according to the overlay image 152. In some embodiments, the adjustment operation includes moving a position of the conductive connector 110 on the first semiconductor structure 100 and/or moving a position of the conductive connector 140 on the second semiconductor structure 130. That is, the overlay image 152 indicates that the position of the conductive connector 110 and/or 140 needs to be adjusted. In some embodiments, the adjustment operation includes conducting a rework or replacement on such conductive connector 110 and/or 140. The rework or replacement may include removing a dislocated conductive connector 110 or 140; and reforming a new conductive connector 110 on the first semiconductor structure 100 or a new conductive connector 140 on the second semiconductor structure 130. Subsequently, their images need to be taken again until the conductive connectors 110 and 140 pass an alignment evaluation.

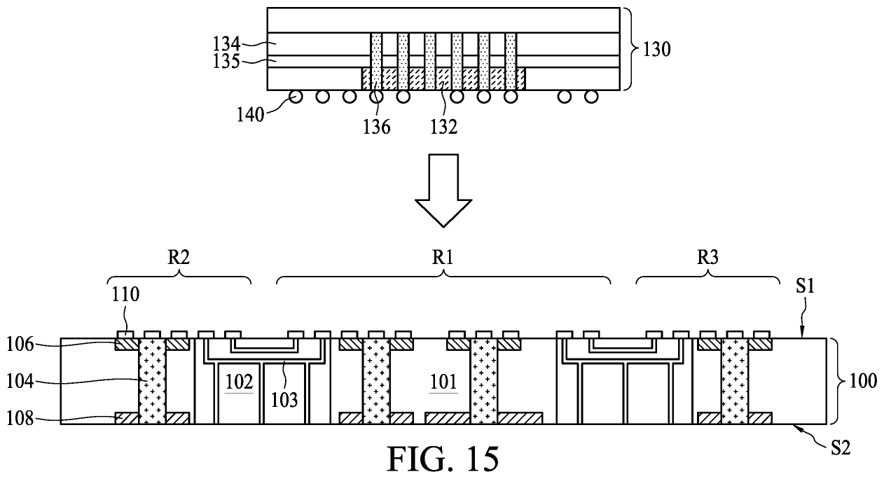

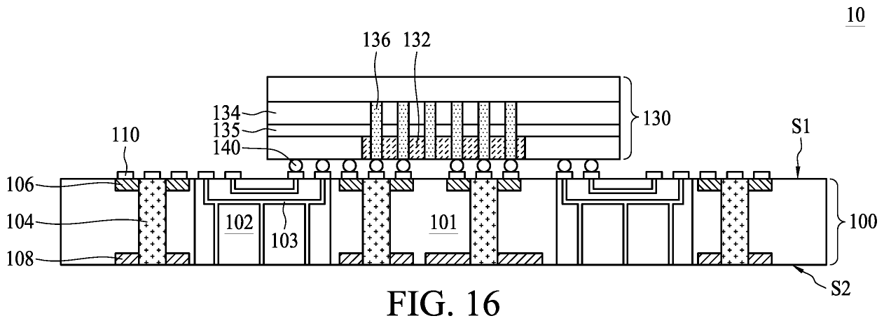

In operation 217, the second semiconductor structure 130 is bonded to the first semiconductor structure 100 to form a semiconductor bonded structure 10, as shown in FIGS. 15 and 16. The second semiconductor structure 130 is aligned to the region R1 of the first semiconductor structure 100. The conductive connectors 140 are attached to the conductive connectors 110 in the region R1 to form the semiconductor bonded structure 10. The second semiconductor structure 130 is electrically coupled to the first semiconductor structure 100 via the conductive connectors 140 and 110. In some embodiments, an inter-chip electrical test is performed on the semiconductor bonded structure 10. After the alignment evaluation and the adjustment operation, an electrical connection between the conductive connectors 110 and 140 is improved.

In some embodiments, a bonding image associated with the bonding of the conductive connectors 110 and the conductive connectors 140 is obtained by the imaging device 120. The bonding image may be used to re-examine or evaluate the alignment of the conductive connectors 110 and 140 after the semiconductor bonded structure 10 is formed.

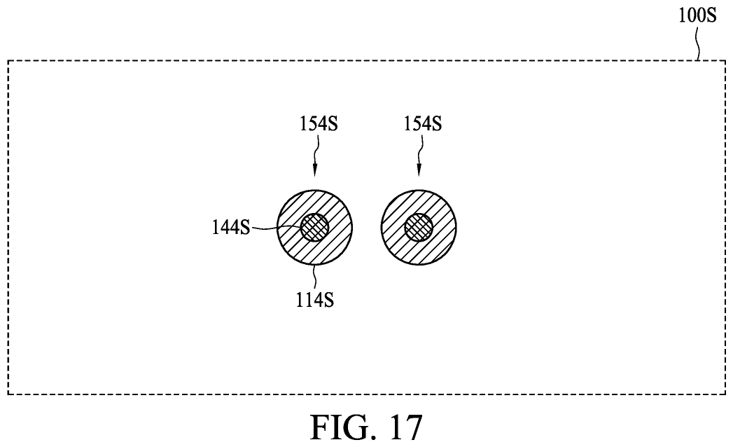

In some other embodiments, the alignment evaluation of operation 215 can be performed in a simulation stage of a design process of a semiconductor bonded structure. FIGS. 17 to 20 show various simulated overlay images, which respectively correspond to real overlay images 152 shown in FIGS. 11 to 14. A semiconductor structure pattern 100S is provided. The semiconductor structure pattern 100S may be associated to the first semiconductor structure 100 or the second semiconductor structure 130. Multiple first connector patterns 114S and multiple second connector patterns 144S are disposed on the semiconductor structure pattern 100S. The first connector patterns 114S and the second connector patterns 144S may be associated to the conductive connectors 110 and the conductive connectors 140, respectively. The first connector pattern 114S and the second connector pattern 144S may have different sizes or shapes. The patterns 100S, 114S and 144S are icons that are separately movable in the simulation images. The first connector pattern 114S may be overlapped by or superimposed with the second connector pattern 144S to generate a connector overlay pattern 154S. In some embodiments, the connector overlay pattern 154S is used to evaluate an alignment of two real conductive connectors bonded to each other.

In the simulation stage of the design process of the semiconductor bonded structure, the first connector pattern 114S and its corresponding second connector pattern 144S can be aligned in such a way that their center points have no deviation. Furthermore, all the first connector patterns 114S and their corresponding second connector patterns 144S can be aligned in a way such that the overall deviations or shifts are substantially zero. However, a layout of conductive connectors formed on a semiconductor structure needs to follow certain design rules. That is, not every conductive connector can be disposed in a desired position on the semiconductor structure. Therefore, in some embodiments, respective positions of the first connector patterns 114S and the second connector patterns 144S of the semiconductor structure pattern 100S are designed to follow the design rules and to minimize the overall deviations.

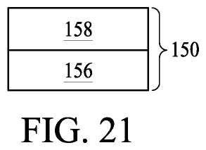

In operation 219, a third semiconductor structure 150 is provided, as shown in FIG. 21. The third semiconductor structure 150 may include an electronic device 156 or multiple electronic devices 156 and 158, multiple through vias (not shown), and multiple metal layers (not shown). In some embodiments, the electronic device 156 or 158 is a memory device, such as a high bandwidth memory (HBM), a dynamic random-access memory (DRAM), a static random-access memory (SRAM), or a combination thereof. In some other embodiments, the electronic device 156 or 158 is a GPU chip, a PMIC die, an RF die, a sensor die, a MEMS die, a DSP die, the like, or a combination thereof. In some embodiments, the third semiconductor structure 150 includes passive components (e.g., capacitors, resistors, inductors, etc.).

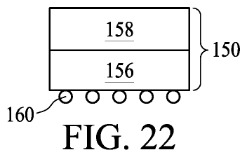

In operation 221, multiple conductive connectors 160 are disposed on one side of the third semiconductor structure 150, as shown in FIG. 22. The conductive connectors 160 may be formed of metals such as copper (Cu), aluminum (Al), gold (Au), nickel (Ni), silver (Ag), platinum (Pt), tin (Sn), or combinations thereof. The conductive connectors 160 can provide the electronic device 156 or 158 with electrical connections to other components. The conductive connectors 160 are designed to correspond to the conductive connectors 110 of the first semiconductor structure 100. The conductive connectors 160 may have various configurations. For example, the conductive connectors 160 may be solder balls, bumps, pads or pillars. The metal pillars may be solder-free and/or may have substantially vertical sidewalls. In some embodiments, the conductive connectors 160 are micro bumps (ubumps) which have a diameter less than 50 micrometers.

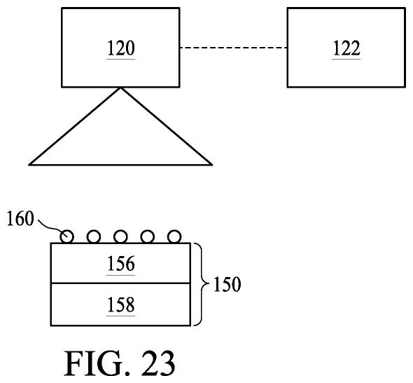

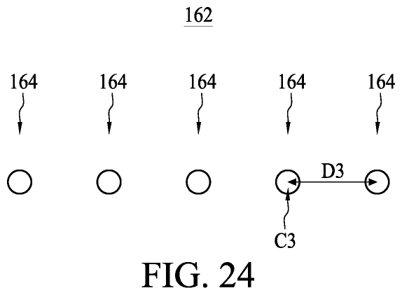

In operation 223, a third image 162 of the conductive connectors 160 is obtained, as shown in FIGS. 23 and 24. Referring to FIG. 23, the imaging device 120 can automatically focus on the conductive connectors 160.

Referring to FIG. 24, the third image 162 is a top view of the conductive connectors 160 on the third semiconductor structure 150. The third image 162 includes multiple connector images 164 of the corresponding conductive connectors 160. Images of other elements of the third semiconductor structure 150 are not shown in FIG. 24 for a purpose of simplicity. In some embodiments, the processor 122 is capable of deriving a distance D3 between center points C3 of two adjacent connector images 164. In some embodiments, the distance D3 correlates to an actual distance between centers of the corresponding conductive connectors 160.

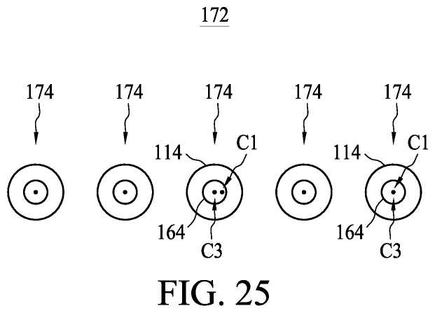

In operation 225, an overlay image 172 based on the first image 112 and the third image 162 is derived, as shown in FIG. 25. The processor 122 may be used to overlap the third image 162 of FIG. 24 with the first image 112 of FIG. 5 to generate the overlay image 172. In some embodiments, the overlay image 172 is used to monitor an alignment degree when the conductive connectors 160 are bonded to the conductive connectors 110. The conductive connectors 160 may be referred to as monitor patterns. The overlay image 172 includes multiple connector overlay images 174 from the connector images 114 and 164.

In some embodiments, the overlap of the first image 112 and the third image 162 is formed by aligning the center points C3 of the third images 162 with the center points C1 of the first images 112. However, in some cases, when most of the center points C1 and C3 are aligned, some of the center points C1 and C3 may not be aligned. Such problem may come from a fact that the first semiconductor structure 100 with the conductive connectors 110 and the third semiconductor structure 150 with the conductive connectors 160 are produced by different manufacturers. Specifications related to size, pitch or shape of the conductive connectors 110 may not be consistent with those of the conductive connectors 160. Another possibility is that one or more of the conductive connectors 110 or 160 may be displaced during manufacturing. Therefore, when some of the center points C3 deviate from their corresponding center points C1, i.e., the center points C1 and C3 have deviations or shifts, the first image 112 and the third image 162 are aligned in such a way that the overall deviations are minimized.

In operation 227, an alignment evaluation is performed on the conductive connectors 160 and the conductive connectors 110 based on the overlay image 172. In some embodiments, before the third semiconductor structure 150 is mounted on the first semiconductor structure 100, an alignment of the conductive connectors 160 with the corresponding conductive connectors 110 is evaluated to reduce possible bonding issues.

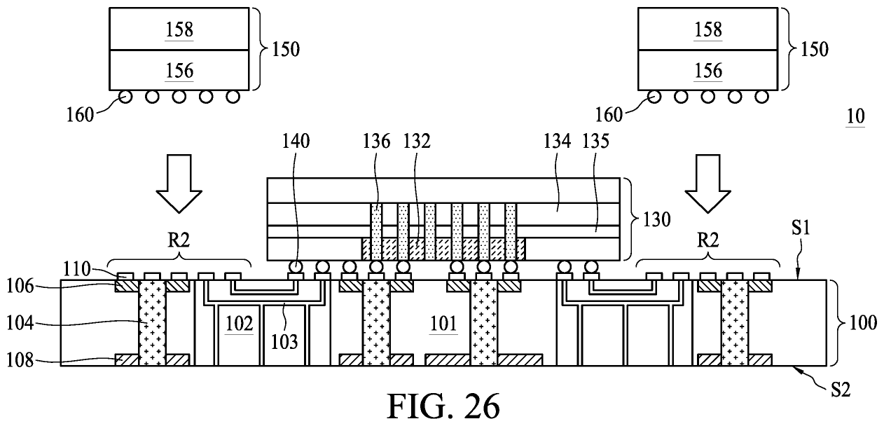

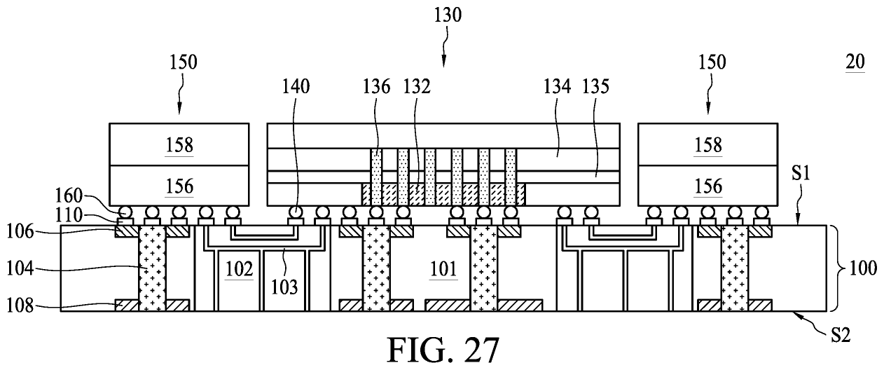

In operation 229, the third semiconductor structure 150 is bonded to the first semiconductor bonded structure 10 to form a semiconductor bonded structure 20, as shown in FIGS. 26 and 27. Referring to FIG. 26, in some embodiments, one third semiconductor structure 150 is aligned to the region R2 of the first semiconductor structure 100, and another third semiconductor structure 150 is aligned to the region R3 of the first semiconductor structure 100. In some other embodiments, only one third semiconductor structure 150 is bonded to the region R2 or the region R3 of the first semiconductor structure 100. Referring to FIG. 27, the conductive connectors 160 are attached to the conductive connectors 110 in the region R2 and/or R3 to form the semiconductor bonded structure 20. The third semiconductor structure 150 is electrically coupled to the first semiconductor structure 100 via the conductive connectors 160 and 110.

In some embodiments, a bonding image associated with the bonding of the conductive connectors 110 and the conductive connectors 160 is obtained by the imaging device 120. The bonding image may be used to re-examine or evaluate the alignment of the conductive connectors 110 and 160 after the semiconductor bonded structure 20 is formed.

Although not specifically illustrated, a molding compound may be used to surround and protect the semiconductor bonded structure 20. The molding compound may be, for example, resin, polyimide, PPS, PEEK, PES, epoxy molding compound (EMC), another material, the like, or a combination thereof. The molding compound may separately encapsulate the first, second and third semiconductor structures 100, 130 and 150 before the semiconductor structures 100, 130 and 150 are bonded.

The semiconductor bonded structure 20 may be referred to as a three-dimensional integrated circuit (3DIC) formed using a chip-on-wafer (CoW) technique or a chip-on-wafer-on-substrate (CoWoS) technique. In some embodiments, the semiconductor bonded structure 20 includes and integrates one or more RDLs, interconnect devices, memory devices, SOC and other electronic devices. In the semiconductor bonded structure 20, the first semiconductor structure 100 is called a bottom die, and the second and third semiconductor structures 130 and 150 are called top dies. The top dies are electrically connected to the bottom die through a multitude of connectors such as the conductive connectors 110, 140 and 160. The through vias (such as through vias 104 and 136) and the conductive connectors 110, 140 and 160 are used to transmit input/output (I/O), ground or power signals among the first, second and third semiconductor structures 100, 130 and 150. When some connectors are misaligned, electrical problems between the top and bottom dies, such as open circuit or short circuit, may occur. Therefore, it is important to align the conductive connectors of the top and bottom dies before completing the fabrication of the semiconductor bonded structure 20.

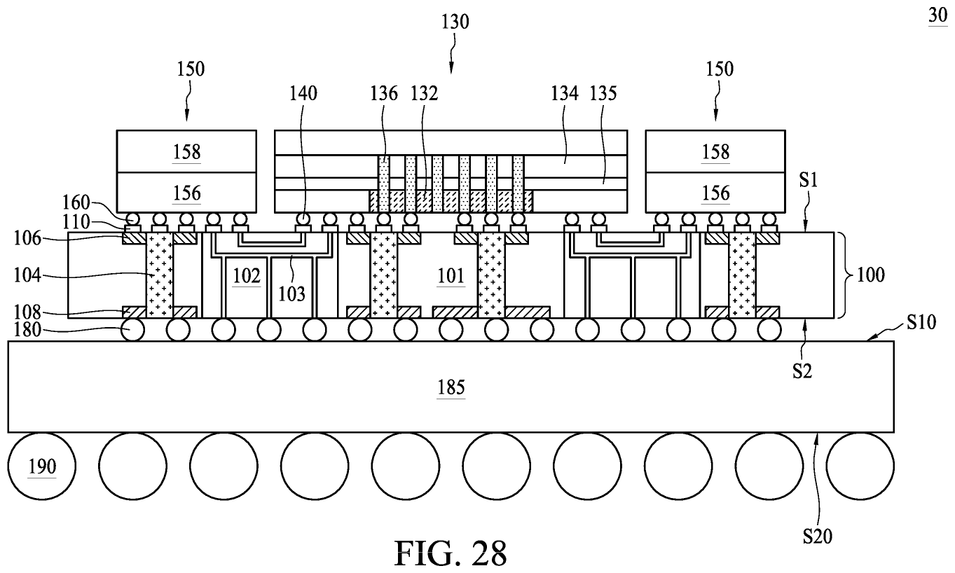

In operation 231, the semiconductor bonded structure 20 is bonded to a substrate 185 to form a semiconductor bonded structure 30, as shown in FIG. 28. The semiconductor bonded structure 20 may be placed on the substrate 185, for example, using e.g., a pick-and-place process. In some embodiments, multiple conductive connectors 180 are disposed on the second side S2 of the first semiconductor structure 100, and the semiconductor bonded structure 20 with the conductive connectors 180 is attached to the substrate 185. In some other embodiments, the conductive connectors 180 are disposed on a first side S10 of the substrate 185, and the semiconductor bonded structure 20 is attached to the conductive connectors 180. The conductive connectors 180 may be formed of metals such as copper (Cu), aluminum (Al), gold (Au), nickel (Ni), silver (Ag), platinum (Pt), tin (Sn), or a combination thereof. The conductive connectors 180 may have various configurations. For example, the conductive connectors 180 may be solder balls, bumps, pads or pillars. In some embodiments, the conductive connectors 180 are controlled collapsed chip connection (C4) bumps. In some embodiments, some of the conductive connectors 180 are electrically connected to the through vias 104 via the second metal layers 108, and some of the conductive connectors 180 are electrically connected to the electronic devices 102. The substrate 185 may be a printed circuit board (PCB) formed of polypropylene (PP) and may be a single-layer or a multilayer structure.

In some embodiments, multiple conductive connectors 190 are disposed on a second side S20 of the substrate 185. The conductive connectors 190 may be formed of metals such as copper (Cu), aluminum (Al), gold (Au), nickel (Ni), silver (Ag), platinum (Pt), tin (Sn), or a combination thereof. The conductive connectors 190 may have various configurations. For example, the conductive connectors 190 may be solder balls, bumps, pads or pillars. In some embodiments, the conductive connectors 190 form a ball grid array (BGA) on the second side S20 of the substrate 185.

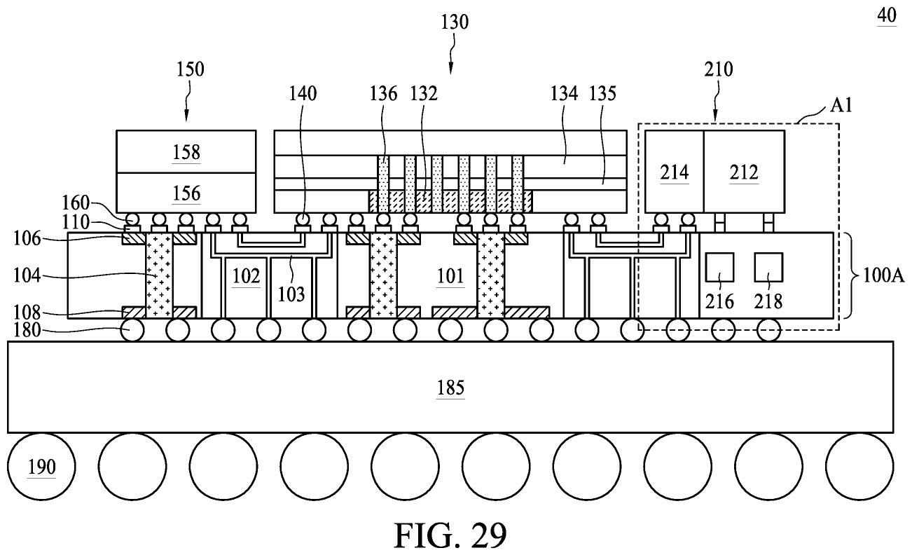

FIG. 29 shows a semiconductor bonded structure 40 according to some other embodiments of the present disclosure. The semiconductor bonded structure 40 is similar to the semiconductor bonded structure 30, except the semiconductor bonded structure 40 includes a fourth semiconductor structure 210 disposed on a fifth semiconductor structure 100A. In some embodiments, the fourth semiconductor structure 210 includes a photonic integrated circuit (PIC) 212 and an electronic integrated circuit (EIC) 214. The EIC 214 may be similar to any one of the electronic devices 102, 132, 134, 156 and 158. The EIC 214 is electrically connected to the fifth semiconductor structure 100A.

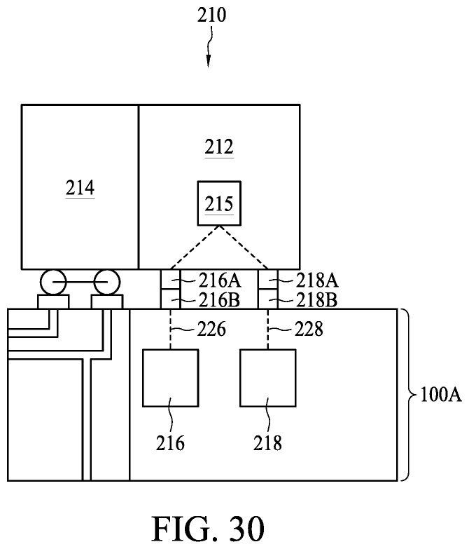

FIG. 30 is enlarged view of a region A1 of FIG. 29. In some embodiments, the PIC 212 includes optical connectors 216A and 218A, a coupler or beam splitter 215 and other optical or photonic components. The fifth semiconductor structure 100A is similar to the first semiconductor structure 100 but includes optical or photonic components. In some embodiments, the fifth semiconductor structure 100A includes a light source 216, a photodetector 218 adjacent to the light source 216, an optical connector 216B coupled to the light source 216 via a waveguide 226 and an optical connector 218B coupled to the photodetector 218 via a waveguide 228. The light source 216 and the photodetector 218 may be photodiodes.

In some embodiments, the optical connector 216A is connected to the optical connector 216B, and the optical connector 218A is connected to the optical connector 218B. In some cases, the fourth semiconductor structure 210 and the fifth semiconductor structure 100A may be produced by different manufacturers. It is possible that the optical connector 216A and the optical connector 218A cannot be respectively connected to the optical connector 216B and the optical connector 218B at the same time because their specifications are different or slightly different. To overcome such problem, in some embodiments, the method used for aligning conductive connectors including the operations 213, 215, 225 and 227 is applicable to an alignment of the optical connector 216A with the optical connector 216B, and an alignment of the optical connector 218A with the optical connector 218B. If an alignment evaluation performed on the optical connectors 216A and 216B or the optical connectors 218A and 218B shows a partial overlap or a non-overlap, the corresponding optical connector 216A, 216B, 218A or 218B needs to be examined. In some cases, such optical connector 216A, 216B, 218A or 218B causing the misalignment may need to be repositioned, reinstalled or replaced.

The light source 216 is coupled to the PIC 212 through the waveguide 226, the optical connector 216B and the optical connector 216A. The photodetector 218 is coupled to the PIC 212 through the waveguide 228, the optical connector 218A and the optical connector 218B. A light generated from the light source 216 may pass through the waveguide 226, the optical connector 216B and the optical connector 216A to the coupler 215. The photodetector 218 may receive the light from the coupler 215 through the optical connector 218A, the optical connector 218B and the waveguide 228.

The present disclosure provides a method for inspecting a semiconductor bonded structure. The method can be used for inspecting bonding connectors between different chips or dies. The method can be used during fabrication of the semiconductor bonded structure. The method includes imaging and overlapping images for an alignment evaluation of conductive connectors disposed on different semiconductor structures. Once any misalignment is detected using the method, suitable operations such as adjusting a position of a conductive connector, replacement with another conductive connector having a different size, or rework of a conductive connector may be performed prior to a bonding operation. The method can be used to detect 3DIC stacking errors prior to a practical production of a 3DIC semiconductor device. In addition, the alignment evaluation provided by the present disclosure can be used in a simulation stage of designing the 3DIC semiconductor device. Using the method provided by the present disclosure, misalignment or design errors between conductive connectors or between optical connectors can be reduced while complying with design rules. As such, electrical transmission or optical transmission of a semiconductor bonded structure can be improved.

One aspect of the present disclosure provides a method for inspecting a semiconductor bonded structure. The method includes: obtaining a first image of a first connector of a first semiconductor structure; obtaining a second image of a second connector of a second semiconductor structure, wherein the second connector corresponds to the first connector; deriving an overlay image based on the first image and the second image; and evaluating an alignment of the first connector and the second connector based on the overlay image.

One aspect of the present disclosure provides another method for inspecting a semiconductor bonded structure. The method includes: designing a first pattern associated with a first connector of a first semiconductor structure; designing a second pattern associated with a second connector of a second semiconductor structure, wherein the first connector corresponds to the second connector; deriving an overlay pattern associated with the first pattern and the second pattern; and evaluating an alignment of the first connector and the second connector based on the overlay pattern.

One aspect of the present disclosure provides another method for inspecting a semiconductor bonded structure. The method includes: bonding a first connector of a first semiconductor structure with a second connector of a second semiconductor structure; obtaining a first bonding image associated with the bonding of the first connector and the second connector; and evaluating an alignment of the first connector and the second connector based on the first bonding image.

The foregoing outlines features of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods and steps.

1. A method for inspecting a semiconductor bonded structure, comprising:
obtaining a first image of a first connector of a first semiconductor structure;
obtaining a second image of a second connector of a second semiconductor structure, wherein the second connector corresponds to the first connector;
deriving an overlay image based on the first image and the second image; and
evaluating an alignment of the first connector and the second connector based on the overlay image.

2. The method of claim 1, wherein the overlay image corresponds to the alignment when the second connector is bonded to the first connector.

3. The method of claim 1, wherein the evaluation of the alignment includes determining whether a portion of the first image is out of the second image or a portion of the second image is out of the first image.

4. The method of claim 3, wherein adjustment operation is performed after the evaluation of the alignment.

5. The method of claim 3, wherein the evaluation determines
whether a first adjustment operation needs to be performed for the first connector of the first semiconductor structure, and
whether a second adjustment operation needs to be performed for the second connector of the second semiconductor structure.

6. The method of claim 5, wherein
the first adjustment operation includes moving a position of the first connector on the first semiconductor structure, and
the second adjustment operation includes moving a position of the second connector on the second semiconductor structure.

7. The method of claim 5, wherein
the first adjustment operation includes replacing the first connector, and
the second adjustment operation includes replacing the second connector.

8. The method of claim 6, after the evaluation of the alignment, further comprising:
bonding the second connector with the first connector to join the second semiconductor structure with the first semiconductor structure.

9. The method of claim 8, after the bonding of the second semiconductor structure to the first semiconductor structure, further comprising performing an electrical test on the first semiconductor structure and the second semiconductor structure.

10. A method for inspecting a semiconductor bonded structure, comprising:
designing a first pattern associated with a first connector of a first semiconductor structure;
designing a second pattern associated with a second connector of a second semiconductor structure, wherein the first connector corresponds to the second connector;
deriving an overlay pattern associated with the first pattern and the second pattern; and
evaluating an alignment of the first connector and the second connector based on the overlay pattern.

11. The method of claim 10, wherein the evaluation of the alignment includes determining whether a portion of the first pattern is out of the second pattern or a portion of the second pattern is out of the first pattern.

12. The method of claim 10, wherein the overlay pattern includes a complete overlap, a partial overlap and a non-overlap.

13. The method of claim 10, wherein the first pattern and the second pattern have different sizes.

14. The method of claim 10, before the derivation of the overlay pattern, further comprising:
aligning the second semiconductor structure with the first semiconductor structure, wherein the overlay pattern includes an offset between a first center point of the first pattern with a second center point of the second pattern.

15. The method of claim 10, after the evaluation of the alignment of the first connector and the second connector, further comprising:
adjusting a position or a size of the first connector on the first semiconductor structure, or
adjusting a position or a size of the second connector on the second semiconductor structure.

16. A method for inspecting a semiconductor bonded structure, comprising:
bonding a first connector of a first semiconductor structure with a second connector of a second semiconductor structure;
obtaining a first bonding image associated with the bonding of the first connector and the second connector; and
evaluating an alignment of the first connector and the second connector based on the first bonding image.

17. The method of claim 16, wherein the first connector and the second connector have different configurations.

18. The method of claim 16, wherein the first semiconductor structure includes an interposer disposed with a local silicon interconnect (LSI), a through-silicon via (TSV) and a redistribution layer (RDL).

19. The method of claim 16, further comprising:
bonding the first connector of the first semiconductor structure with a third connector of a third semiconductor structure, wherein the third semiconductor structure is adjacent to the second semiconductor structure;
obtaining a second bonding image associated with the bonding of the first connector and the third connector; and
evaluating an alignment of the first connector and the third connector based on the second bonding image.

20. The method of claim 19, wherein the second semiconductor structure is an electronic integrated circuit (EIC) and the third semiconductor structure is a photonic integrated circuit (PIC).
